(19) United States
(12) Patent Application Publication
(10) Pub. No.: US 2016/0007467 A1
(43) Pub. Date: Jan. 7, 2016

(54) PACKAGE STRUCTURE AND MANUFACTURING METHOD THEREOF

(71) Applicant: Samsung Electro-Mechanics Co., Ltd., Suwon-Si (KR)

(72) Inventors: Seung-Eun LEE, Seongnam (KR); Myung-Sam KANG, Hwaseong (KR); Jun-Oh HWANG, Hwaseong (KR); Seung-Yeop KOOK, Busan (KR); Ki-Jung SUNG, Suwon (KR); Young-Kwan LEE, Busan (KR)

(21) Appl. No.: 14/790,994

(22) Filed: Jul. 2, 2015

(30) Foreign Application Priority Data
Jul. 2, 2014 (KR) 10-2014-0082567

(51) Int. Cl. H05K 1/18; H05K 1/11; H05K 1/02; H05K 3/28; H05K 3/30

(52) U.S. Cl. CPC H05K 1/182; H05K 3/28; H05K 3/301; H05K 1/0271; H05K 1/11; H05K 2201/10931; H05K 2203/06

(57) ABSTRACT

A package structure and a method of manufacturing the package structure are disclosed. The package structure in accordance with an aspect of the present invention includes: a stiffener substrate; a dielectric layer and a circuit pattern layer laminated on the stiffener substrate; a protective layer laminated on the dielectric layer so as to protect the circuit pattern layer; a first electrode post protruded by penetrating the protective layer from the circuit pattern layer; and a chip receiving portion formed on a surface of the protective layer that is in a protruded direction of the first electrode post.

### CROSS-REFERENCE TO RELATED APPLICATIONS

This application claims the benefit of Korean Patent Application No. 10-2014-0082567, filed with the Korean Intellectual Property Office on Jul. 2, 2014, the disclosure of which is incorporated herein by reference in its entirety.

### BACKGROUND

1. Technical Field

The present invention relates to a package structure and a method for manufacturing the same.

2. Background Art

New forms and various types of package substrates, which are mainly used for substrates for memory package, have been constantly developed in order to cope with the demands for smaller, faster and more functional electronic devices.

Particularly, making the package substrates smaller and thinner has been an important task, and there have been a number of studies for packaging a larger capacity memory in higher integration.

However, if the substrate for memory package failed to hold out with sufficient rigidity during the manufacturing process thereof, the substrate would suffer with warpage, which would be more significant as the substrate becomes thinner due to the increasingly smaller and thinner electronic device.

As a result, this can be a major cause of decreased yield when package-on-package products are manufactured, and thus there is a need for a study for a package structure with which the productivity can be improved.

The related art of the present invention is disclosed in Korea Patent Publication No. 2001-0056778 (laid open on Jul. 4, 2001).

### SUMMARY

The present invention provides a package structure and a manufacturing method thereof that can improve the yield by preventing warpage.

An aspect of the present invention features a package structure, which includes: a stiffener substrate; a dielectric layer and a circuit pattern layer laminated on the stiffener substrate; a protective layer laminated on the dielectric layer so as to protect the circuit pattern layer; a first electrode post protruded by penetrating the protective layer from the circuit pattern layer; and a chip receiving portion formed on a surface of the protective layer that is in a protruded direction of the first electrode post.

Here, the package structure can further include: a first chip being installed on the chip receiving portion; and a sealing layer being laminated on the protective layer so as to cover the first chip and to be penetrated by the first electrode post.

The stiffener substrate can be made of a metallic material containing invar.

The package structure can further include a package substrate having a second chip installed thereon and having a second electrode post protruded thereon and coupled with the first electrode post.

Another aspect of the present invention features a method of manufacturing a package structure that includes: laminating a dielectric layer and a circuit pattern layer on a stiffener substrate; laminating a protective layer on the dielectric layer so as to protect the circuit pattern layer; forming a first electrode post being protruded by penetrating the protective layer from the circuit pattern layer; and forming a chip receiving portion on a surface of the protective layer that is in a protruded direction of the first electrode post.

Here, the method of manufacturing a package structure can further include: installing a first chip on the chip receiving portion; and laminating a sealing layer on the protective layer so as to cover the first chip and to be penetrated by the first electrode post.

The stiffener substrate can be made of a metallic material containing invar.

The method of manufacturing a package structure can further include: coupling a second electrode post of a package substrate, which has a second chip installed and the second electrode post protruded thereon, with the first electrode post.

### BRIEF DESCRIPTION OF THE DRAWINGS

FIG. 1 is a perspective view showing a portion of a package structure in accordance with an embodiment of the present invention.

FIG. 2 is a cross-sectional view showing a portion of the package structure in accordance with an embodiment of the present invention.

FIG. 3 shows an example of a package-on-package through the package structure in accordance with an embodiment of the present invention.

FIG. 4 is a flow diagram showing a method of manufacturing a package structure in accordance with an embodiment of the present invention.

### DETAILED DESCRIPTION

Hereinafter, a package structure and a method of manufacturing the same in accordance with certain embodiments of the present invention will be described in detail with reference to the accompanying drawings. In describing the present invention with reference to the accompanying drawings, any identical or corresponding elements will be assigned with same reference numerals, and no redundant description thereof will be provided.

Terms such as “first” and “second” can be used for merely distinguishing one element from another identical or corresponding element, but the above elements shall not be restricted to the above terms.

When one element is described to be “coupled” to another element, it does not refer to a physical, direct contact between these elements only, but it shall also include the possibility of yet another element being interposed between these elements and each of these elements being in contact with said yet another element.

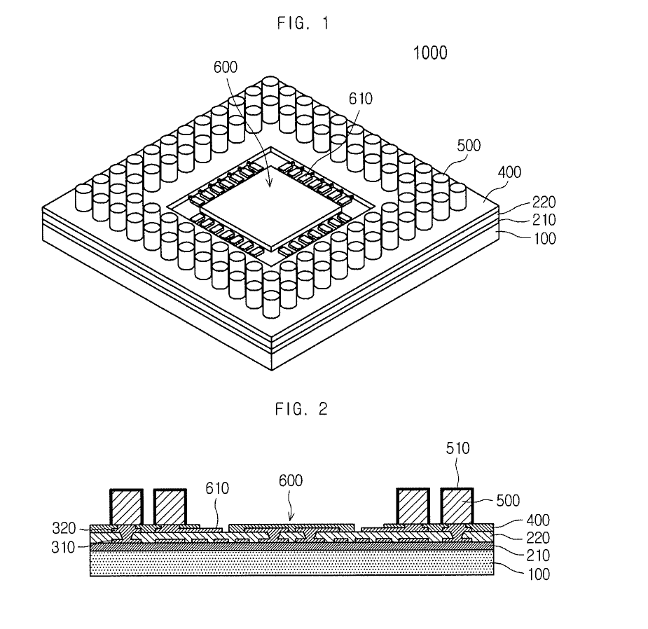

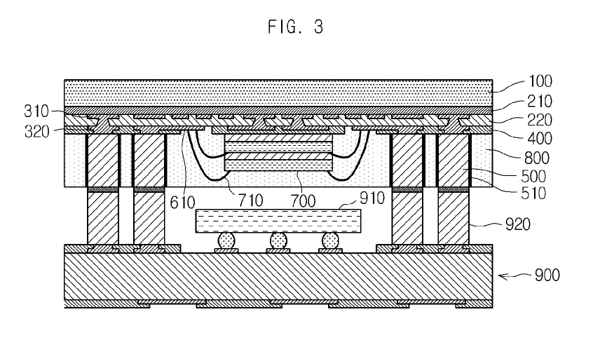

FIG. 1 is a perspective view showing a portion of a package structure in accordance with an embodiment of the present invention. FIG. 2 is a cross-sectional view showing a portion of the package structure in accordance with an embodiment of the present invention. FIG. 3 shows an example of a package-on-package through the package structure in accordance with an embodiment of the present invention.

As illustrated in FIG. 1 to FIG. 3, a package structure 1000 in accordance with an embodiment of the present invention includes a stiffener substrate 100, dielectric layers 210, 220, circuit pattern layers 310, 320, a protective layer 400, first electrode posts 500 and a chip receiving portion 600, and can further include a first chip 700, a sealing layer 800 and a package substrate 900.

The stiffener substrate 100, which is a member having a predetermined rigidity, can support one surface of the package structure 1000 in accordance with the present embodiment to prevent warpage. This stiffener substrate 100 can be formed to have a predetermined area or thickness according to the shape of the package structure 1000.

The dielectric layers 210, 220 and the circuit pattern layers 310, 320 are both laminated on the stiffener substrate 100 and, as shown in FIG. 1 to FIG. 3, can be successively laminated on the stiffener substrate 100 to form an electric circuit and an insulated coating structure for the electric circuit in order for performing a predetermined function.

Here, the circuit pattern layers 310, 320 can be each formed through an etching method using photolithography or an additive method (i.e., plating method) and can be connected with each other through a via that penetrates the dielectric layer 220. However, the present invention shall not be limited to what is described herein and can be variously modified as necessary.

The protective layer 400, which is laminated on the dielectric layer 220 so as to protect the circuit pattern layer 320, can cover the circuit pattern layer 320, as shown in FIG. 1 to FIG. 3, to prevent the circuit pattern layer 320 from being exposed.

Here, the protective layer 400 can be formed with, for example, a solder resist and have portions of the circuit pattern layer 320 exposed by having portions of the solder resist removed through exposure and development processes.

The first electrode posts 500, which are protruded by penetrating the protective layer 400 from the circuit pattern layers 310, 320, can be connection members for electrically connecting the circuit pattern layers 310, 320 with specific external portions. For example, as shown in FIG. 3, the first electrode posts 500 can each have one end thereof electrically connected with the circuit pattern layers 310, 320 and the other end thereof electrically connected with second electrode post 920, which will be described later. As such, the first electrode posts 500 can electrically connect the circuit pattern layers 310, 320 with specific external portions. Here, when necessary, external surfaces of the first electrode posts 500 can be processed to have coating layers 510, such as OSP (Organic Solderability Preservative), formed thereon.

The chip receiving portion 600 is a portion formed on a surface of the protective layer 400 that is in the protruded direction of the first electrode posts 500. As shown in FIG. 1 to FIG. 3, in the package structure 1000 in accordance with the present embodiment, the chip receiving portion 600 and the first electrode posts 500 can be formed on a same surface.

In such a case, the chip receiving portion 600 can become a portion where a first chip 700, which will be described later, is mounted and can be configured by including a bonding pad 610, which is exposed by removing a portion of the protective layer 400, and an adhesive member, to which the first chip 700 is attached.

As described above, since the package structure 1000 in accordance with the present embodiment has a build-up layer formed on the stiffener substrate 100, it is possible to prevent warpage of the package structure 1000 and improve the yield. Particularly, as the stiffener substrate 100, which can maintain rigidity against warpage, does not have to be removed and can be permanently used, warpage can be reduced even if a thinner dielectric layer is used.

The first chip 700, which is installed in the chip receiving portion 600, can be configured in various ways by including an electronic element, such as a semiconductor chip, according to a function and use. Here, as illustrated in FIG. 3, the first chip 700 can be electrically connected with the bonding pad 610 through a bonding wire 710, but the present invention shall not be limited to what is illustrated herein and can be configured in various ways, for example, having the first chip 700 installed through a flip chip method.

The sealing layer 800, which covers the first chip 700 and is laminated on the protective layer 400 so as to be penetrated by the first electrode posts 500, can fix and protect the first chip 700 by sealing the first chip 700.

Particularly, since the ends of the first electrode posts 500 are exposed by penetrating the sealing layer 800, the first chip 700 and the first electrode posts 500 can be formed on a same plane in the package structure 1000 in accordance with the present embodiment.

As the first chip 700 and the fires electrode posts 500 are formed on the same plane in the package structure 1000 in accordance with the present embodiment, the first chip 700 can be disposed inside a package-on-package product when the package-on-package product is manufactured, as shown in FIG. 3.

The package structure 1000 including the stiffener substrate 100, the dielectric layers 210, 220, the circuit pattern layers 310, 320, the protective layer 400, the first electrode posts 500, the chip receiving portion 600, the first chip 700 and the sealing layer 800 can be a single package that constitutes the package-on-package product as shown in FIG. 3.

In the package structure 1000 in accordance with the present embodiment, the stiffener substrate 100 can be made of a metallic material containing invar. Here, the invar can be an alloy containing 63.5% iron and 36.5% nickel and can have a relatively very small coefficient of thermal expansion.

In order for the stiffener substrate 100 to prevent warpage effectively, it is preferable to have a small coefficient of thermal expansion so that little change in volume is resulted despite a change in temperature.

Accordingly, by using the stiffener substrate 100 containing the invar, the package structure 1000 of the present embodiment can prevent warpage of the package structure 1000 more effectively.

The package substrate 900, which has a second chip 910 mounted thereon and has protruded second electrode posts 920 coupled with the first electrode posts 500 thereon, can be another package that constitutes the package-on-package product shown in FIG. 3.

In other words, similarly to the first chip 700, the second chip 910 can be configured by including an electronic element, such as a semiconductor chip, and installed on the package substrate 900. Moreover, the package substrate 900 can also have separate dielectric layers, circuit pattern layers and protective layer formed thereon, and the second electrode posts 920 can be also protruded by penetrating the protective layer from the circuit pattern layers of the package substrate 900, similarly to the first electrode posts 500.

The package-on-package product can be formed by having the second electrode posts 920 and the first electrode posts 500 coupled with one another.

As described above, in the package structure 1000 in accordance with the present embodiment, packages are connected with one another by use of the first electrode posts 500 and the second electrode posts 920, without using additional solder balls, and thus electrical connection can be made more easily and more precisely.

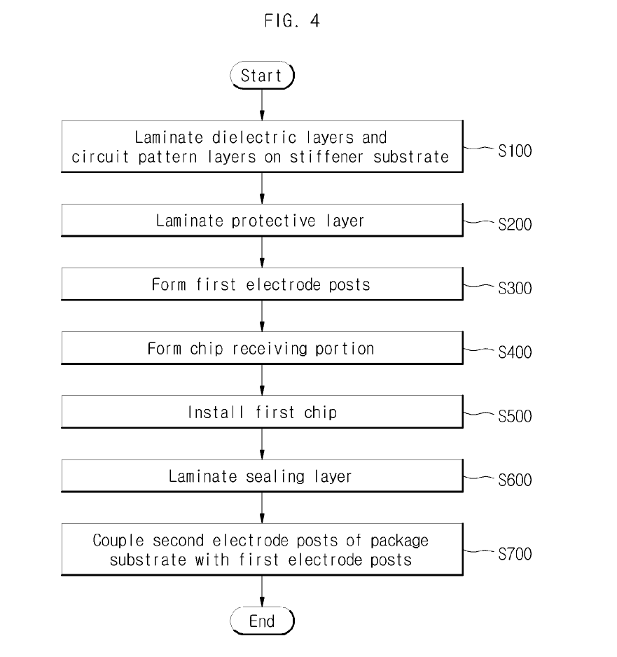

FIG. 4 is a flow diagram showing a method of manufacturing a package structure in accordance with an embodiment of the present invention. Here, for the convenience of description and understanding, elements expressed in the method of manufacturing a package structure in accordance with an embodiment of the present invention will be described with reference to FIG. 1 to FIG. 3.

As shown in FIG. 4, the method of manufacturing a package structure in accordance with an embodiment of the present invention starts with laminating dielectric layers 210, 220 and circuit pattern layers 310, 320 on a stiffener substrate 100 (S100).

Specifically, the dielectric layers 210, 220 and the circuit pattern layers 310, 320 can be successively laminated on the stiffener substrate 100 to form an electric circuit and an insulated coating structure for the electric circuit in order for performing a predetermined function.

Then, a protective layer 400 can be laminated on the dielectric layer 220 so as to protect the circuit pattern layer 320 (S200). Here, the protective layer 400 can be formed with, for example, a solder resist and have portions of the circuit pattern layer 320 exposed by having portions of the solder resist removed through exposure and development processes.

Next, first electrode posts 500, which are protruded by penetrating the protective layer 400 from the circuit pattern layer 320, can be formed (S300). Specifically, the first electrode posts 500 can each have one end electrically connected with the circuit pattern layers 310, 320 and the other end exposed so as to be electrically connected with a specific external portion.

Next, a chip receiving portion 600 can be formed on a surface of the protective layer 400 that is in the protruded direction of the first electrode posts 500 (S400). In such a case, the chip receiving portion 600 can become a portion where a first chip 700 is mounted and can be configured by including a bonding pad 610, which is exposed by removing a portion of the protective layer 400, and an adhesive member, to which the first chip 700 is attached.

As described above, in the method of manufacturing a package structure in accordance with the present embodiment, a build-up layer is formed on the stiffener substrate 100, and thus it is possible to prevent warpage of the package structure 1000 and improve the yield. Particularly, as the stiffener substrate 100, which can maintain rigidity against warpage, does not have to be removed and can be permanently used, warpage can be reduced even if a thinner dielectric layer is used.

The method of manufacturing a package structure in accordance with the present embodiment can further include installing the first chip 700 on the chip receiving portion 600 (S500). Here, the first chip 700 can be electrically connected with the bonding pad 610 through a bonding wire 710, but the present invention shall not be limited to what is described herein and can be configured in various ways, for example, having the first chip 700 installed through a flip chip method.

Afterwards, a sealing layer 800 can be formed on the protective layer 400 so as to cover the first chip 700 and to be penetrated by the first electrode posts 500 (S600).

Here, since the ends of the first electrode posts 500 are exposed by penetrating the sealing layer 800, the first chip 700 and the first electrode posts 500 can be formed on a same plane in the package structure.

As the first chip 700 and the fires electrode posts 500 are formed on the same plane in the method of manufacturing a package structure in accordance with the present embodiment, the first chip 700 can be disposed inside a package-on-package product when the package-on-package product is manufactured.

In the method of manufacturing a package structure in accordance with the present embodiment, the stiffener substrate 100 can be made of a metallic material containing invar.

Accordingly, by using the stiffener substrate 100 containing the invar, the method of manufacturing a package structure according to the present embodiment can prevent warpage of the package structure more effectively.

The method of manufacturing a package structure in accordance with the present embodiment can further include coupling second electrode posts 920, which have a second chip 910 mounted thereon, of a package substrate 900, on which the second electrode posts 920 are formed and protruded, with the first electrode posts 500 (S700). That is, by having the second electrode posts 920 coupled with the first electrode posts 500, the package-on-package product can be formed. As a result, in the method of manufacturing a package structure in accordance with the present embodiment, packages are connected with one another by use of the first electrode posts 500 and the second electrode posts 920, without using additional solder balls, and thus electrical connection can be made more easily and more precisely.

Since every element associated with the method of manufacturing a package structure in accordance with an embodiment of the present invention have been described in detail in association with the package structure 1000 in accordance with an embodiment of the present invention, and thus will not be described redundantly.

Although a certain embodiment of the present invention has been described hitherto, it shall be appreciated that the present invention can be variously modified and permutated by those of ordinary skill in the art to which the present invention pertains by supplementing, modifying, deleting and/or adding an element without departing from the technical ideas of the present invention, which shall be defined by the claims appended below. It shall be also appreciated that such modification and/or permutation are also included in the claimed scope of the present invention.

1. A package structure comprising:
a stiffener substrate;
a dielectric layer and a circuit pattern layer laminated on the stiffener substrate;
a protective layer laminated on the dielectric layer so as to protect the circuit pattern layer;
a first electrode post protruded by penetrating the protective layer from the circuit pattern layer; and
a chip receiving portion formed on a surface of the protective layer that is in a protruded direction of the first electrode post.

2. The package structure of claim 1, further comprising:
a first chip being installed on the chip receiving portion; and
a sealing layer being laminated on the protective layer so as to cover the first chip and to be penetrated by the first electrode post.

3. The package structure of claim 2, wherein the stiffener substrate is made of a metallic material containing invar.

4. The package structure of claim 1, further comprising a package substrate having a second chip installed thereon and having a second electrode post protruded thereon and coupled with the first electrode post.

5. A method of manufacturing a package structure, comprising:
laminating a dielectric layer and a circuit pattern layer on a stiffener substrate;
laminating a protective layer on the dielectric layer so as to protect the circuit pattern layer;
forming a first electrode post being protruded by penetrating the protective layer from the circuit pattern layer; and
forming a chip receiving portion on a surface of the protective layer that is in a protruded direction of the first electrode post.

6. The method of claim 5, further comprising:
installing a first chip on the chip receiving portion; and
laminating a sealing layer on the protective layer so as to cover the first chip and to be penetrated by the first electrode post.

7. The method of claim 6, wherein the stiffener substrate is made of a metallic material containing invar.

8. The method according to claim 5, further comprising:
coupling a second electrode post of a package substrate with the first electrode post, the package substrate having a second chip installed and the second electrode post protruded thereon.
